(19) United States
(12) Patent Application Publication
(10) Pub. No.: US 2023/0367114 A1
(43) Pub. Date: Nov. 16, 2023

(54) AUTOMATED METALENS DESIGN SYSTEM

(71) Applicant: Synopsys, Inc., Mountain View, CA (US)

(72) Inventors: Jan BOS, Glanerbrug (NL); Robert SCARMOZZINO, Montrose, NY (US); Mayank BAHL, Hawthorne, NY (US); Evan K. HELLER, Glastonbury, CT (US); Chenglin XU, Katonah, NY (US)

(21) Appl. No.: 17/741,335

(22) Filed: May 10, 2022

(51) Int. Cl. G02B 27/00; G06F 30/10

(52) U.S. Cl. CPC G02B 27/0012; G06F 30/10

(57) ABSTRACT

A method for designing a metalens includes receiving a description of an optical system, including (i) a meta-atom to be used in a first lens in the optical system and (ii) a first distance from the first lens, receiving a description of optical signals, including (i) an incident optical signal to the optical system and (ii) a target optical signal of the optical system and determining a first layout of a plurality of the meta-atom on the first lens. The method further includes determining a first output optical signal of the optical system based at least in part on the incident optical signal and the first layout of the plurality of the meta-atom on the first lens and setting a design of the first lens using the first layout.

### TECHNICAL FIELD

The present disclosure relates to the design of optical systems. In particular, the present disclosure relates to a system and method for providing automated metalens design.

### BACKGROUND

Optical systems may include lenses that redirect or refocus light signals. The relatively flat surface topology for metasurfaces as well as mature semiconductor fabrication techniques make metasurfaces ideal for a wide range of applications, including lens design (e.g., for optical systems operating in either transmission or reflection mode).

### SUMMARY

Systems and methods for designing a metalens are described herein. According to an embodiment, a method for designing a metalens includes receiving a description of an optical system. The description of the optical system indicates (i) characteristics of a first lens in the optical system, (ii) a meta-atom to be used in the first lens, and (iii) a first distance from the first lens. The method also includes receiving a description of optical signals, the description of the optical signals describing (i) an incident optical signal to the optical system and (ii) a target optical signal of the optical system and determining, based at least in part on the characteristics of the first lens, the meta-atom, and the first distance, a first layout of a plurality of the meta-atom on the first lens. The method further includes determining a first output optical signal of the optical system based at least in part on the incident optical signal and the first layout of the plurality of the meta-atom on the first lens and setting a design of the first lens using the first layout based on whether a difference between the first output optical signal and the target optical signal meets a threshold.

The method may include, based on the difference between the first output optical signal and the target optical signal not meeting the threshold, determining, based at least in part on the characteristics of the first lens, the meta-atom, the first distance, and the first layout, a second layout of the plurality of the meta-atom on the first lens. The method may also include determining a second output optical signal of the optical system with the incident optical signal and with the second layout of the plurality of the meta-atom on the first lens and setting the design of the first lens using the second layout based on whether a difference between the second output optical signal and the target optical signal meets the threshold.

The description of the optical system may indicate characteristics of a second lens in the optical system and a second distance from the second lens. The first distance may be between the first lens and the second lens in the optical system and determining the first layout may be based on the characteristics of the second lens and the second distance.

Determining the first layout may include determining a geometric design parameter for each of the plurality of the meta-atom on the first lens.

The first layout may be based on different incident angles for each of the plurality of the meta-atom.

The first layout may be based on a polarization of the optical signal and a response for each of the plurality of the meta-atom to the polarization.

The first output optical signal may be based at least in part on an absorbing boundary condition of a space within the first distance from the first lens.

The difference may include a difference between an intensity profile of the first output optical signal and an intensity profile of the target optical signal scaled by a scale factor.

The difference may be based on a phase of the first output optical signal and on a phase of the target optical signal.

According to another embodiment, a system includes a memory and a processor communicatively coupled to the memory. The processor receives (i) characteristics of a first lens in an optical system, (ii) a meta-atom to be used in the first lens, and (iii) a first distance from the first lens and receives a description of (i) an incident optical signal to the optical system and (ii) a target optical signal of the optical system. The processor also determines, based at least in part on the characteristics of the first lens, the meta-atom, and the first distance, a first layout of a plurality of the meta-atom on the first lens and determines a first output optical signal of the optical system based at least in part on the incident optical signal and the first layout of the plurality of the meta-atom on the first lens. The processor further sets a design of the first lens using the first layout based on whether a difference between the first output optical signal and the target optical signal meets a threshold.

The processor may, based on the difference between the first output optical signal and the target optical signal not meeting the threshold, determine, based at least in part on the characteristics of the first lens, the meta-atom, the first distance, and the first layout, a second layout of the plurality of the meta-atom on the first lens. The processor may also determine a second output optical signal of the optical system with the incident optical signal and with the second layout of the plurality of the meta-atom on the first lens and set the design of the first lens using the second layout based on whether a difference between the second output optical signal and the target optical signal meets the threshold.

The processor may receive characteristics of a second lens in the optical system and a second distance from the second lens. The first distance may be between the first lens and the second lens in the optical system. Determining the first layout may be based on the characteristics of the second lens and the second distance.

Determining the first layout may include determining a geometric design parameter for each of the plurality of the meta-atom on the first lens.

The first layout may be based on different incident angles for each of the plurality of the meta-atom.

The first layout may be based on a polarization of the optical signal and a response for each of the plurality of the meta-atom to the polarization.

The first output optical signal may be based at least in part on an absorbing boundary condition of a space within the first distance from the first lens.

The difference may include a difference between an intensity profile of the first output optical signal and an intensity profile of the target optical signal scaled by a scale factor.

The difference may be based on a phase of the first output optical signal and on a phase of the target optical signal.

According to another embodiment, a non-transitory computer readable medium stores instructions for designing a metalens that, when executed by a processor, cause the processor to receive (i) characteristics of a first lens in an optical system, (ii) a meta-atom to be used in the first lens, and (iii) a first distance from the first lens and receive a description of (i) an incident optical signal to the optical system and (ii) a target optical signal of the optical system. The processor also determines, based at least in part on the characteristics of the first lens, the meta-atom, and the first distance, a first layout of a plurality of the meta-atom on the first lens, determined a first output optical signal of the optical system based at least in part on the incident optical signal and the first layout of the plurality of the meta-atom on the first lens, and sets a design of the first lens using the first layout based on whether a difference between the first output optical signal and the target optical signal meets a threshold.

The processor may, based on the difference between the first output optical signal and the target optical signal not meeting the threshold, determine, based at least in part on the characteristics of the first lens, the meta-atom, the first distance, and the first layout, a second layout of the plurality of the meta-atom on the first lens, determine a second output optical signal of the optical system with the incident optical signal and with the second layout of the plurality of the meta-atom on the first lens, and set the design of the first lens using the second layout based on whether a difference between the second output optical signal and the target optical signal meets the threshold.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 illustrates an example optical system.

FIG. 2 illustrates an example metalens in the optical system of FIG. 1.

FIG. 3A illustrates an example meta-atom array.

FIG. 3B illustrates an example meta-atom array.

FIG. 3C illustrates an example meta-atom array.

FIG. 4 illustrates an example process for designing a metalens in the optical system of FIG. 1.

FIG. 5 is a flowchart of an example method for designing a metalens.

FIG. 6 depicts a diagram of an example computer system in which embodiments of the present disclosure may operate.

### DETAILED DESCRIPTION

Aspects of the present disclosure relate to an automated metalens design system. Optical systems may include lenses that redirect or refocus light signals. The relatively flat surface topology for metasurfaces as well as mature semiconductor fabrication techniques make metasurfaces ideal for a wide range of applications, including lens design (e.g., for optical systems operating in either transmission or reflection mode). For example, including metalenses in an optical system may reduce the size of the optical system and may reduce alignment challenges.

Each metalens in the optical system is formed using an array of meta-atoms on a surface. The meta-atoms are sub-wavelength structures that may be of any suitable shape and size. For example, the meta-atoms may be rectangular pillars of any suitable width. As another example, the meta-atoms may be cylinders of any suitable width.

Computational simulation has been used to examine the underlying physics of metasurfaces and for providing insights into the design of optical systems that contain both metalenses and typical lenses. Due to the range of geometric structure sizes involved in these optical systems, where the system itself as well as the metalenses might be centimeters in size and the meta-atoms forming the metalenses may be sub-micron in size, a variety of numerical techniques are used to efficiently and accurately analyze performance and optimize efficiency. Conventional (e.g., ray-tracing-based) optical design methods, however, may not accurately simulate such optical systems due to the limitations of geometric optics. Furthermore, more rigorous electro-magnetic simulation methods are resource intensive and may not be used for optimization of these systems due to the large number of sub-wavelength structures in these metalenses.

The present disclosure describes a system that automatically determines the design of metalenses in an optical system. Generally, a user provides the system a description of the optical system (e.g., the types of lenses in the optical system, the meta-atoms to be used for one or more of the metalenses in the optical system, and the distance between the lenses) and a description of light signals in the system (e.g., characteristics of an incident light signal and characteristics of a desired, target light signal to be output by the optical system). The system then applies an adjoint method-based optimization process to determine the layout of the metalenses in the optical system (e.g., the size or arrangement of the meta-atoms that form the metalenses) such that the optical system outputs a light signal that is within a threshold of the target light signal given the incident light signal.

The present system provides several technical advantages over the conventional design processes, in certain embodiments. For example, the present system takes into account non-unity transmission, different incident angles, and polarizations when determining the layout of the metalenses, which improves how accurately the system simulates and optimizes the behavior of the optical system. Additionally, the present system allows for the optical system to include both metalenses and typical lenses. As a result, the present system may be used to design an optical system for multi-wavelength applications, multi-functional devices, larger fields of view, and polarization sensitive devise.

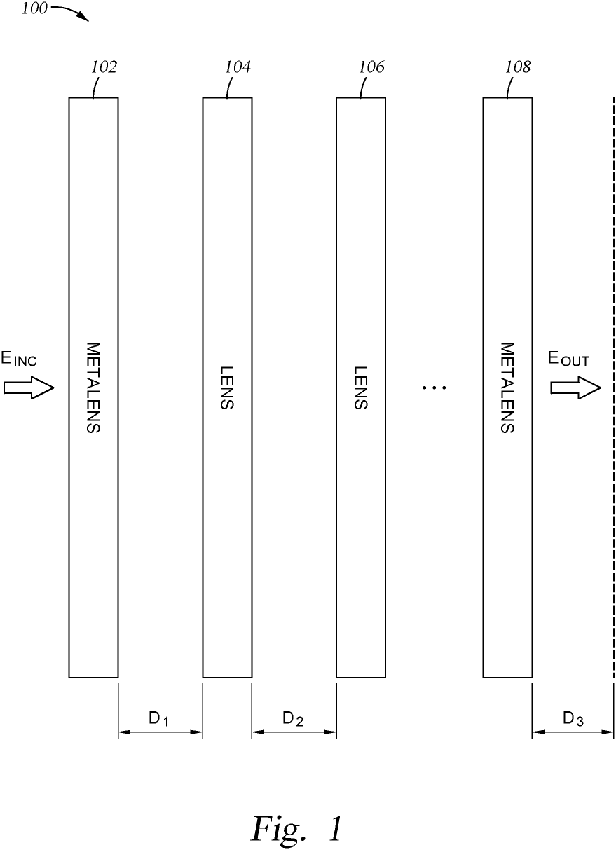

FIG. 1 illustrates an example optical system 100. As seen in FIG. 1, the optical system 100 includes an arrangement of lenses and metalenses. The optical system 100 may include any suitable number of lenses and metalenses arranged in any suitable manner. An incident optical signal (E_{INC}) passes through the optical system 100. The lenses and metalenses split or redirect the incident optical signal to produce one or more output optical signals (E_{OUT}). The properties and arrangement of the lenses and metalenses may be set so that the optical system 100 produces the desired optical signals.

In the example of FIG. 1, the optical system 100 includes multiple lenses and metalenses. Specifically, the optical system 100 includes a first metalens 102, a first lens 104, a lens 106, and a second metalens 108. The optical system 100 may include additional lenses and metalenses. It is further appreciated that the optical system may include any number and arrangement of lens and metalenses without deviating from the scope of the present disclosure. The first metalens 102 is separated from the first lens 104 by a distance D₁. The first lens 104 is separated from the second lens 106 by a distance D₂. The lenses and metalenses may be positioned with any desired distance between them. An incident optical signal passes through the first metalens 102, the first lens 104, the second lens 106, and the second metalens 108. The first metalens 102, the first lens 104, the second lens 106, and the second metalens 108 split or redirect the optical signal as the optical signal passes through the first metalens 102, the first lens 104, the second lens 106, and the second metalens 108. The second metalens 108 produces the one or more output optical signals E_{OUT} of the optical system 100. The first metalens 102, the first lens 104, the second lens 106, and the second metalens 108 may be arranged such that the one or more output optical signals produce a desired intensity profile at a distance D₃ from the metalens 108. In other words, the properties of the first metalens 102, the first lens 104, the second lens 106, and the second metalens 108 may be selected and the distances D₁, D₂, and D₃ may be set so that the one or more output optical signals produce one or more desired intensity profiles at the distance D₃ from the metalens 108.

The lenses 104 and 106 may be typical thin lenses whose thickness is much smaller relative to their radii of curvature. As a result, the lenses 104 and 106 may be modeled by a phase transfer function. The metalenses 102 and 108 may be formed using meta-atoms, which are underlying sub-wavelength structures. Each metalens 102 or 108 includes an array of meta-atoms.

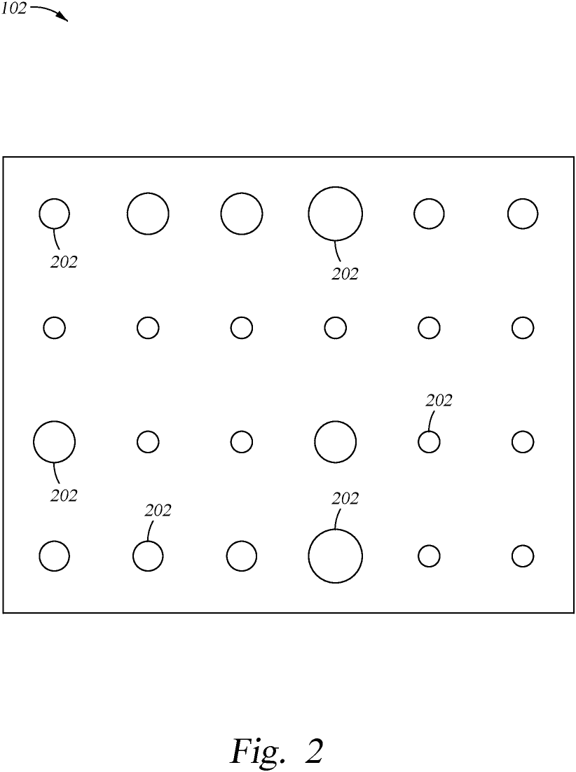

FIG. 2 illustrates an example metalens 102 in the optical system 100 of FIG. 1. Generally, the metalens 102 is formed using an array of meta-atoms. The meta-atoms may be any suitable shape or size. For example, the meta-atoms may be cylindrical, square pillars, or cross-shaped pillars. A geometric design parameter of the meta-atom may be adjusted to control how the metalens splits or redirects incident optical signals. For example, a width or a diameter of the meta-atom may be adjusted to control how the metalens splits or redirects incident optical signals.

As seen in FIG. 2, the metalens 102 includes an array of meta-atoms 202. For clarity, not all of the meta-atoms 202 in the first metalens 102 have been labeled in FIG. 2. The meta-atoms 202 in the array may be of different widths or diameters. For example, some of the meta-atoms 202 may have a smaller width or diameter relative to other meta-atoms 202 in the array. These widths or diameters may be selected so that the metalens 102 splits or redirects incident optical signals in a desired manner.

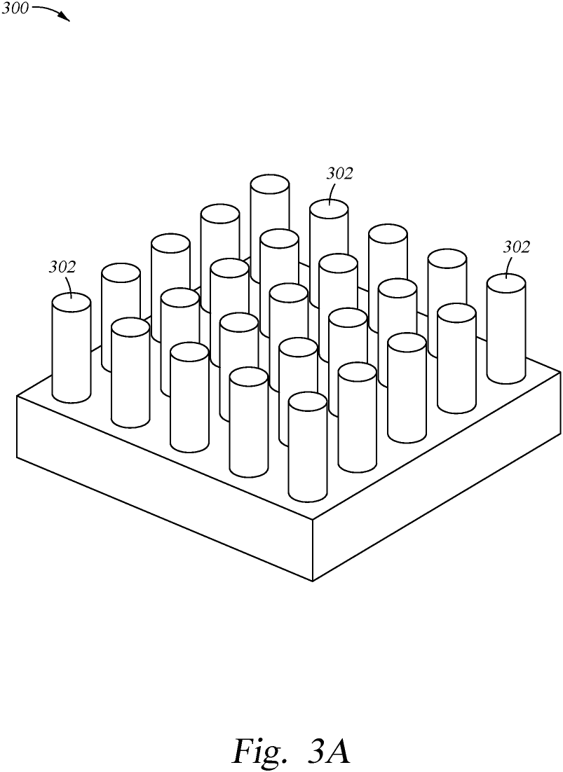

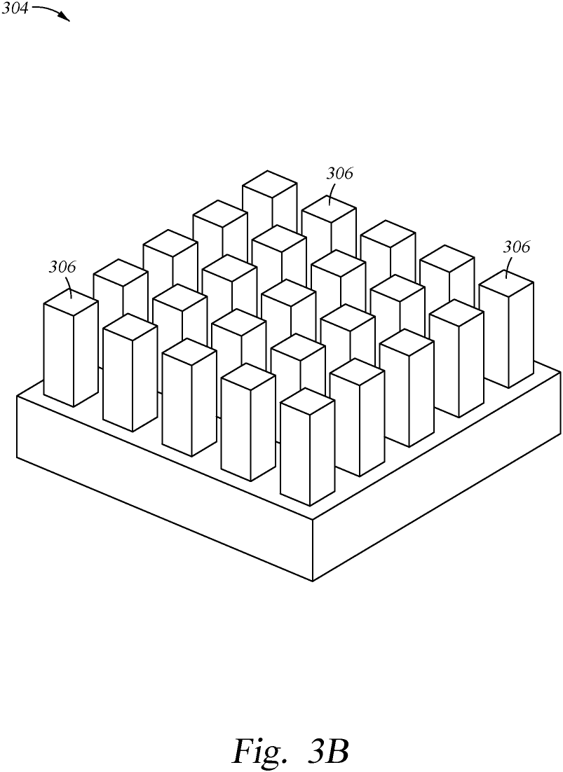

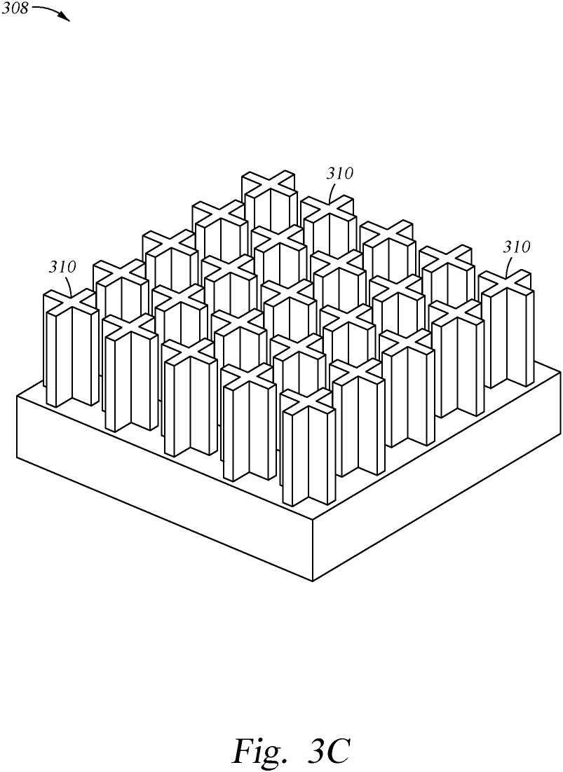

FIG. 3A illustrates an example array 300 of meta-atoms. As seen in FIG. 3A, the array 300 is formed using cylindrical meta-atoms 302. For clarity, not all of the meta-atoms 302 in the array 300 are labeled in FIG. 3A. FIG. 3B illustrates an example array 304 of meta-atoms. As seen in FIG. 3B, the array 304 includes rectangular pillar meta-atoms 306. For clarity, not all of the meta-atoms 306 in the array 304 are labeled in FIG. 3B. FIG. 3C illustrates an example array 308 of meta-atoms. As seen in FIG. 3C, the array 308 includes cross shaped pillar meta-atoms 310. For clarity, not all of the meta-atoms 310 in the array 308 are labeled. Although the previous figures show the meta-atoms for a metalens having particular shapes, the meta-atoms for a metalens may be any suitable shape.

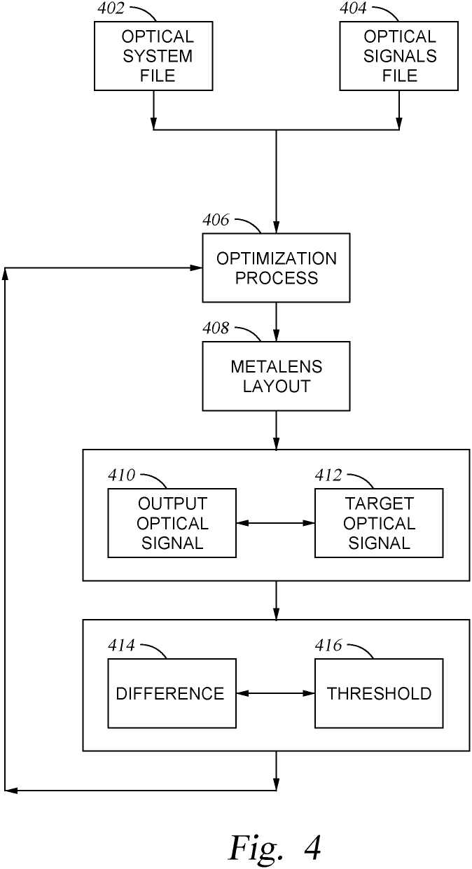

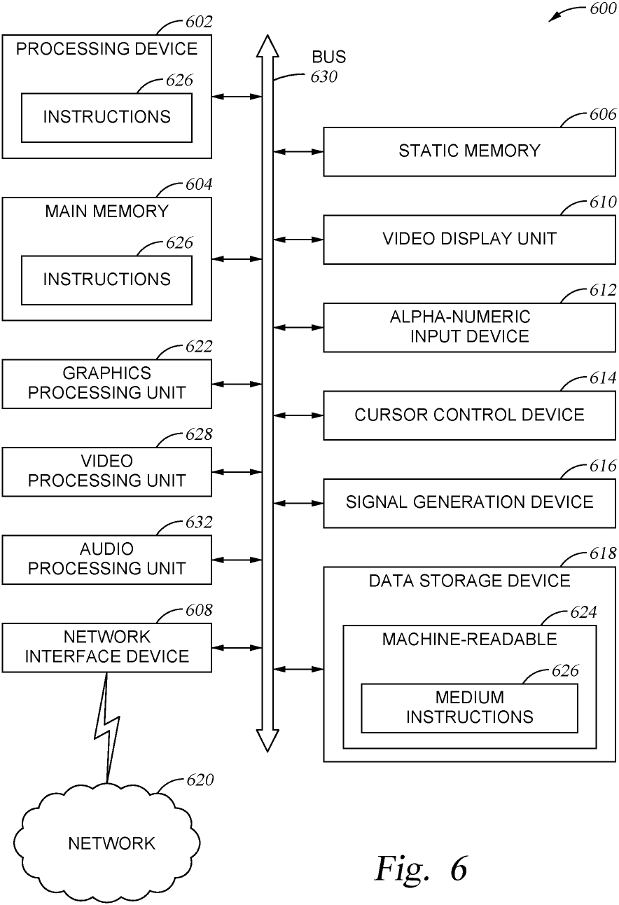

FIG. 4 illustrates an example process for designing a metalens in the optical system 100 of FIG. 1. A computer system, such as the computer system 600 of FIG. 6, may perform the process described in FIG. 4. Generally, the computer system uses a specified arrangement of the optical system 100 and specified characteristics of incident and output optical signals to determine the structure of the meta-atoms on the metalenses in the optical system 100. In particular embodiments, the computer system produces a design for the metalenses in the optical system 100 that allow the optical system 100 to produce an output optical signal that is closer to a desired optical signal.

The computer system receives an optical system file 402. The optical system file 402 includes a description of the optical system 100, including characteristics of the lenses and metalenses (e.g., size and shape of the lens or metalens), and specifying the arrangement of the lenses and metalenses in the optical system 100. For example, the optical system file 402 may indicate the ordering/arrangement of the lenses and metalenses in the optical system 100. Additionally, the optical system file 402 may indicate the distances between the arrangement of metalenses and lenses in the optical system 100. Furthermore, the optical system file 402 may specify the distance at which a desired characteristic of an output optical signal of the optical system 100 should be measured. For example, the optical system file 402 may indicate the distance at which the intensity profile of the output optical signal should be measured. The computer system may use the information in the optical system file 402 to determine the design for the metalenses specified in the optical system file 402.

Moreover, the optical system file 402 may specify the particular meta-atoms to be used for the metalenses. For example, the optical system file 402 may specify that a metalens in the optical system 100 should use cylindrical meta-atoms. As another example, the optical system file 402 may specify that another metalens in the optical system 100 should use rectangular pillar meta-atoms. The optical system file 402 may specify that any suitable number of metalenses in the optical system 100 should use any suitable type of meta-atom.

As an example, the optical system file 402 may define the optical system as a sequence of metalenses and typical thin lenses with specified distances between each lens, and with the final distance being to the image plane. The optical system file 402 may be a plain text file defining one or more lens specifications, with one lens per line, as in:
<specification for lens #0>
<specification for lens #1>

Each lens specification may include a sequence of keyword-value pairs. If the lens is a metalens (as opposed to a typical lens) the computer system can use a database library that contains the performance characteristic of each meta-atom as a function of wavelength, incident angle, polarization, meta-atom design parameter(s), etc. The database for a metalens can be specified through the “database” keyword by setting database=<user_defined_dbname> on its corresponding line in the optical system file 402. If the database keyword is not specified for a metalens, a virtual idealized atom database is used which has one parameter with linear phase response with a 360 degree range and perfect transmission. A typical thin lens can be specified by setting the “thinlens” keyword to 1, and its focal length can be specified through the “flens” keyword.

The distance to the next lens, or the distance to the final image plane for the last lens can be specified through the “length” keyword. The final image distance may be overridden in each individual test case. The size of the lens, which is the area where meta-atoms are to be placed for the metalens or the diameter of a typical lens, is specified through the “size” keyword and the lens is ideally apertured outside this area (e.g., the transmission is 0). The shape of the lens is specified through the “shape” keyword and could be set to circle which yields a circular aperture, and may default to rectangular. The orientation of the database which specifies the side (substrate or background) light is impinging from can be specified via the “swapfb” keyword. The refractive index of the medium on either side of the lens is inferred from the “database,” which contains the information about the meta-atom substrate or background indices. If a database is not present, the refractive indices on either side of the lens can be specified via the “nin” and “nout” keywords. The range of values over which the meta-atom parameters are constrained are inferred from the database but can be overridden via the “pmin” and “pmax” keywords for each design parameter of the meta-atom.

An example optical system file 402 describing a doublet lens separated by glass 500 µm thick, with circular aperture of diameter 300 µm, the same meta-atom patterning on both sides, and focusing at 1000 µm from the second lens is shown below:
database=meta_atom_bsdf_data length=500 size=300 shape=circle swapfb=1
database=meta_atom_bsdf_data length=1000 size=300 shape=circle

The computer system also receives an optical signals file 404. The optical signals file may specify characteristics of the incident optical signals to the optical system 100. For example, the optical signals file 404 may specify a wavetype and/or a wavelength of the incident optical signal. Additionally, the optical signals file 404 may specify the desired characteristics of one or more output optical signals of the optical system 100. For example, the optical signals file may specify a desired wavelength or a desired intensity profile of one or more output optical signals of the optical system 100. The computer system may use the optical signals file 404 to determine the design of the metalenses in the optical system 100.

As an example, the optical signals file 404 defines multiple objectives to be met simultaneously by the optical system. The optical signals file 404 may be a plain text file defining one or more objectives, with one objective per line, as in:
<specification for test case #0>
<specification for test case #1>

Each objective specification includes a sequence of keyword-value pairs. The objectives can be defined over multiple wavelengths, multiple polarizations, and multiple input patterns/launch angles. The “Einc” keyword specifies the incident field impinging on the optical system. This can be specified by either a file name or prefix, or an expression in brackets (“[]”). The “[]” syntax may also be used to run any command line utility or Python script which can generate a field file allowing user customization. The desired intensity profile is specified through the “Ides” keyword. Alternatively, the desired field profile can be specified through the “Edes” keyword. These support the same options as “Einc” specified above. The wavelength at which the simulation will be performed is specified through the “lambda” keyword. The relative weight of this objective compared to other objectives is specified through the “weight” keyword. The “length” keyword may be used to override the distance to the image plane following the last lens. For polarization situations the “Einc”, “Edes” and “Ides” keywords can have a “_y” suffix to indicate the y component of the field.

An example optical signals file 404 describing diffraction-limited spot as the desired images for three wavelengths (0.64 µm, 0.54 µm, and 0.46 µm) with plane-wave input, and with each objective having the same weight, is shown below:
Einc=[--type=planewave] Ides=[--type=airy] lambda=0.64
Einc=[--type=planewave] Ides=[--type=airy] lambda=0.54
Einc=[--type=planewave] Ides=[--type=airy] lambda=0.46

The computer system analyzes the information in the optical system file 402 and the optical signals file 404 and uses an adjoint method-based optimization process to determine characteristics for the metalenses in the optical system 100. The computer system uses the information in the optical system file 402 and the optical signals file 404 as input to the optimization process 406. The optimization process 406 analyzes the information in the optical system file 402 and the optical signals file 404 to determine a metalens layout 408. The metalens layout 408 may indicate a design parameter for the meta-atoms in a metalens in the optical system 100. The optimization process 406 may predict any suitable number of metalens layouts 408 for any suitable number of metalenses in the optical system 100. The metalens layout 408 may specify any suitable design perimeter for the meta-atoms in the metalens. For example, the metalens layout 408 may specify a width or a diameter of the meta-atoms in the metalens. As discussed previously the metalens layout 408 may specify different widths or diameters for different meta-atoms in the metalens.

The computer system determines an output optical signal 410 using the metalens layout 408 determined by the optimization process 406. The output optical signal 410 is the optical signal output by the optical system 100 when the metalens in the optical system 100 uses the metalens layout 408. The computer system may use any suitable technique to determine the output optical signal 410 of the optical system 100. For example, the computer system may simulate the path of an incident optical signal specified in the optical signal files 404 through the optical system 100 with the metalenses set according to their respective predicted metalens layouts 408. The computer system then determines the output optical signal 410 of the optical system 100 after the incident optical signal has passed through the lenses and metalenses of the optical system 100. In some embodiments, the computer system retrieves, from a database, information about the behavior and characteristics of the desired meta-atoms for the metalens. The computer system may use this information to determine how the metalens in the metalens layouts 408 will split or redirect optical signals when simulating the paths of the optical signals.

The computer system then compares the output optical signal 410 with a target optical signal 412. The target optical signal 412 may have been specified by the optical signals file 404. The target optical signal 412 may be the desired output optical signal specified in the optical signals file 404. For example, the target optical signal 412 may include a desired intensity profile at a particular distance from the optical system 100. The computer system may simulate the output optical signal 410 at the distance from the optical system 100 and compare the output optical signal 410 to the target optical signal 412 to determine a difference 414 between the output optical signal 410 and the target optical signal 412. The desired intensity profile of the target optical signal 412 is scaled by a scale factor before determining the difference 414. The scale factor is automatically determined by the computer system as part of the optimization process 406.

The computer system analyzes the difference 414 to determine whether the metalens layout 408 is acceptable. The computer system compares the difference 414 to a threshold 416. The threshold 416 may be preselected and set according to the desires for the optical system 100. For example, the threshold 416 may be set at 0.001, which is dimensionless and can be interpreted as a fraction of the total intensity. If the difference 414 is within the threshold 416, then the computer system may set the layout of the metalens in the optical system 100 as the metalens layout 408. If the difference 414 exceeds the threshold 416, then the computer system reevaluates the metalens layout 408. The computer system provides the difference 414 as an additional input to the optimization process 406. The optimization process 406 then reevaluates the information in the optical system file 402 and the optical signals file 404 in view of the difference 414 to determine a new metalens layout 408. The computer system then evaluates the new metalens layout 408 to see if a new difference 414 meets the threshold 416. This process continues until the difference 414 meets the threshold 416. The computer system then sets the design parameter of the metalens according to the metalens layout 408.

As an example, the computer may determine one or more geometric design parameters (e.g., width or diameter) of a meta-atom for a metalens in the following manner. In this design approach, the physical parameters of the meta-atom are directly optimized and their effects in terms of behavior with non-unity transmission, different incident angles, and polarizations are directly incorporated. Moreover, the design approach allows for designing optical systems composed of a mix of multiple typical thin lenses and multiple metalenses with unique metasurfaces. The design approach employs the adjoint method to determine the gradients with respect to all physical parameters of each independent meta-atom in the system efficiently. By determining the physical parameters of the meta-atoms in the system, the computer system determines the layouts for each metalens in the system. The metric for optimization is composed from the multiple test cases specified via the optical signals file 404, which include among other things the incident field and the corresponding desired output fields at the image plane (e.g., the distance from the optical system at which the output optical signal 410 is measured). The metric, M, is mathematically described as follows:

$$M = \frac{1}{{\sum }_{t c = 1}^{N} {w}_{t c}} {\sum }_{t c = 1}^{{N}_{t c}} {w}_{t c} \left(\frac{{\int }_{A} {\left({I}_{o u t} \left(x , y\right) - s c a l e ∗ {I}_{d e s} \left(x , y\right)\right)}^{2} . d A}{{\int }_{A} {\left(s c a l e ∗ {I}_{d e s} \left(x , y\right)\right)}^{2} . d A}\right) \qquad \text{(Eq 1)}$$

where Iₒᵤₜ(x, y) and I_{des}(x, y) are the current and desired intensity at the (x, y) location on the image plane, and the integral is evaluated over an area A corresponding to the transverse simulation domain or a subset of it as desired by the user. The field is discretized on a grid and the integration is done numerically. N_{tc} is the total number of test cases, the weight assigned to a testcase is denoted by w_{tc}, and the metric is normalized with the sum of these weights. In the case of polarization, there are two options that can be considered for the metric: the first is to treat Iₒᵤₜ(x, y) as the sum of the intensities due to Eₓ and E_{y}, and the second is to have separate terms for (Iₒᵤₜ - scale _{*} I_{des})² for x and y polarizations. In addition, if the desired target is specified as a field using E_{des} the metric can be adjusted suitably to account for phase.

The computer system introduces a scale factor and automatically chooses the scale factors for each test case. This eliminates the need for a priori scaling of the desired intensity. The scale factors can be chosen using one of two techniques. First, they can be chosen by directly optimizing the metric with respect to the scale factor, holding all else constant, and alternating between optimization of the scale factors and optimization of the design parameters in a co-optimization loop. The direct optimization of the scale factors is performed by analytically calculating

$$\frac{d M}{d \left(s c a l e\right)} ,$$

setting it to 0, and solving analytically for scale. Second, the scale factors could be directly made a part of the set of optimization variables.

The field at the image plane, E^{out}, is calculated from the incident field, E^{inc} as:

$${\text{E}}^{o u t} = \left({\prod }_{L = {N}_{L}}^{1} {\text{D}}^{L} {\text{T}}^{L}\right) {\text{E}}^{i n c} \qquad \text{(Eq 2)}$$

The index, L, corresponds to a lens in the optical system (thin lens or metalens) with N_{L} being the total number of lenses. Note the product symbol denotes an ordering where the terms are ordered such that the lower index is on the left and the upper index is on the right. If the lens is a typical thin lens, its transmission matrix can be defined in multiple ways namely via an analytical phase shift, a user-defined amplitude/phase profile, or one obtained via Zernike polynomials. If the lens is a metalens, the computer system uses a general non-unitary transmission matrix, T^{L}, whose elements are function of (p,λ,φ,θ), where p represents the set of design parameters for the meta-atoms of the metalens, λ denotes the wavelength at which the testcase is being simulated, and ϕ and θ are the local polar and azimuth angles of incidence at each transverse site. For example, in the context of a scalar case with no nearest neighbor interaction, the transmission matrix T^{L} will be diagonal as follows:

$$\begin{matrix}{\text{T}}^{L} = \\ \left[\begin{matrix}a \left({\text{p}}_{1}^{L} , \text{λ} , {\text{φ}}_{1}^{L} , {\text{θ}}_{1}^{L}\right) {e}^{i ϕ \left({\text{p}}_{1}^{L} , \text{λ} , {\text{φ}}_{1}^{L} , {\text{θ}}_{1}^{L}\right)} & & \\ & ⋱ & \\ & & a \left({\text{p}}_{{N}_{A L}}^{L} , \text{λ} , {\text{φ}}_{{N}_{A L}}^{L} , {\text{θ}}_{{N}_{A L}}^{L}\right) {e}^{i ϕ \left({\text{p}}_{{N}_{A L}}^{L} , \text{λ} , {\text{φ}}_{{N}_{A L}}^{L} , {\text{θ}}_{{N}_{A L}}^{L}\right)}\end{matrix}\right]\end{matrix} \qquad \text{(Eq 3)}$$

The above is readily extended to incorporate polarization by allowing T^{L} to be block diagonal with a Jones Matrix representing each block, and to incorporate nearest neighbor effects by allowing T^{L} to be a more general but still sparse matrix. T^{L} in Eq 2 has dimensions N_{A} × N_{A} where N_{A} is (Nx*Ny), Nx and Ny being the number of transverse field values. However, to simplify notation examples like Eq 3 will only refer to the active area of the lens with the understanding the transmission is fixed outside.

Returning to the special case of Eq 3, N_{AL} is the total number of active meta-atom sites on the L^{th} lens, and

$${\text{p}}_{1}^{L} \text{to} {\text{p}}_{{N}_{A L}}^{L}$$

are the vectors of design parameters corresponding to a meta-atom on each transverse site of the L^{th} metalens. The computer system determines the local angles

$$\left({\text{φ}}_{1}^{L} , … … , {\text{φ}}_{{N}_{A L}}^{L}\right) \text{and} \left({\text{θ}}_{1}^{L} , … … , {\text{θ}}_{{N}_{A L}}^{L}\right)$$

based on the field incident at the L^{th} metalens through one of two approaches. The first is to fit the phase profile in the neighborhood of the point to a smooth function and determine the local k-vector from

$$\frac{d ϕ}{d x} \text{and} \frac{d ϕ}{d y} ,$$

from which the angles can be calculated readily. It is important to first wrap the phase before fitting, and that the fitted function be of reasonably low order compared to the number of points in order to smooth insignificant fluctuations in the phase and detect the primary angle of incidence. A simple linear fit was found adequate. An alternative approach was to perform a local Fourieranalysis in the neighborhood of the point, and either use a weighted average of the spectrum in k-space or find the peak in k-space through fitting.

The active area of the lens may be different than the simulation domain with the lens being apertured outside this area and having a fixed value for the transmission. The complex transmission coefficients of the meta-atoms, a(p, λ, ϕ, θ)e^{iϕ(pλϕ,θ)}, are calculated using electro-magnetic simulations over a desired range of the design parameters, wavelength, and angles. This information may be stored in a pre-built database library that may be accessed rapidly during the optimization process. The above transmission coefficient becomes a Jones type matrix when handling polarization and can also include the effects of multiple orders and reflection.

For propagation in homogeneous regions between lenses and from the last lens to the image plane, the computer system uses a non-unitary free space propagator, D^{L}, which is based on Fourier optics and incorporates absorbing boundary conditions (ABC) in the formulation. The propagation matrix, D^{L}, is defined as:

$${\text{D}}^{L} = {\prod }_{i = 1}^{{N}_{s} {}^{L}} {A}^{L} {\text{F}}^{- 1} {\text{K}}^{L} \text{F} \qquad \text{(Eq 4)}$$

where F and F⁻¹are the fast Fourier transform (FFT) and its inverse, respectively, K^{L} is the matrix defining the phase change for each plane wave in k-space, A^{L} is the matrix defining the ABC, and

$${N}_{s} {}^{L}$$

is the number of propagation steps. Without an ABC, the free space propagator is implemented with a discrete Fourier transform (DFT) over a finite domain and employs the FFT algorithm for performance. The DFT (not the FFT per se), is subject to two problems. The first is that artificial reflections from the boundaries of the simulation domain createsignificant errors in the field in the interior of the domain of interest. The second is that power is unable to escape the domain and it is impossible to accurately measure the efficiency of the lens. The simulation domain can be artificially expanded beyond the aperture of the lens, and data in this extended area ignored. But to be effective, the expansion may need to be considerable, increasing the size and cost of the FFT significantly. As an alternative, the computer system may use a small expansion of the simulation domain, and place a tailored absorber in the expansion area, and replace the normal free space propagator with an FFT-based Beam Propagation Method in this region as indicated in Eq 4. The absorber characteristics as well as the propagation step size are automatically chosen based on simulation domain and diffraction considerations related to the aperture. The use of this ABC effectively removes artifacts in the domain of interest and allows power to be calculated readily. Both the propagation and transfer mechanism may be readily replaced by other techniques without altering the proposed design flow.

The optimization strategy employs the adjoint method to determine the gradients of the optimization metric for a given testcase, M_{tc}, with respect to all physical parameters of the meta-atom efficiently:

$$\frac{d {M}_{t c}}{d {p}_{r}^{L}} = 4 R e \left({\text{E}}^{H , L - 1} \text{Δ} {\text{T}}_{r}^{H , L} {\underbrace{{\text{D}}^{H , L} {\prod }_{l = L + 1}^{{N}_{L}} {\text{T}}^{H , l} {\text{D}}^{H , l} ⋅ \text{a}}}_{{b}^{L}}\right) \qquad \text{(Eq 5)}$$

where the conjugate transpose of a matrix A is denoted by A^{H} ≡ A̅^{T}, Re denotes the real part, r is an index into the solution vector of meta-atom design parameters p, and the adjoint field, a, is defined as:

$$\text{a} = \frac{1}{{\int }_{A} {\left(s c a l e ∗ {I}_{d e s} \left(x , y\right)\right)}^{2} . d A} ∗ \left[\begin{matrix}{E}_{1}^{o u t} \left({I}_{1}^{o u t} - s c a l e ∗ {I}_{1}^{d e s}\right) \\ ⋮ \\ {E}_{{N}_{A}}^{o u t} \left({I}_{{N}_{A}}^{o u t} - s c a l e ∗ {I}_{{N}_{A}}^{d e s}\right)\end{matrix}\right] \qquad \text{(Eq 6)}$$

and

$$\text{Δ} {\text{T}}_{r}^{H , L}$$

is a general matrix representing the change in transmission with respect to

$${p}_{r}^{L} .$$

As an example, in the context of scalar case with no nearest neighbor interaction, the matrix

$$\text{Δ} {\text{T}}_{r}^{H , L}$$

will be diagonal matrix with a single non-zero element based on the derivative of the transmission coefficient with respect to the meta-atom design parameter given by

$$\text{Δ} {\text{T}}_{r}^{H , L} = \left[\begin{matrix}0 & & & & \\ & ⋱ & & & \\ & & {\left(\frac{d {T}^{H}}{d p}\right|}_{{p}_{r}^{L}} & & \\ & & & ⋱ & \\ & & & & 0\end{matrix}\right] \qquad \text{(Eq 7)}$$

The above is readily extended to incorporate polarization by allowing

$$\text{Δ} {\text{T}}_{r}^{H , L}$$

to be block diagonal with a Jones Matrix derivative representing the single non-zero block, and to incorporate nearest neighbor effects by allowing

$$\text{Δ} {\text{T}}_{r}^{H , L}$$

to be a more general but still sparse matrix. When the gradients are evaluated in decreasing order of L in Eq 5, then b^{L} can be updated efficiently as

$${\text{b}}^{L - 1} = {\text{D}}^{H , L - 1} {\text{T}}^{H , L} {\text{b}}^{L} , {\text{b}}^{{N}_{L}} = {\text{D}}^{H , {N}_{L}} ⋅ \text{a} \qquad \text{(Eq 8)}$$

and E^{H,L-1} can be stored while applying Eq 2 in increasing order of L.

The above flow can be used with any gradient based optimizer. For example, the optimizer may be a Limited-memory Broyden-Fletcher-Goldfarb-Shanno algorithm with box constraints (L-BFGS-B). The fabrication design rules are incorporated by constraining the range of design parameters for the unique meta-atoms and using them as box constraints in the optimizer. The computer system uses several heuristics for the initial guess as input to the optimizer. By default, it sets the initial design parameters uniformly over the surface of each metalens and at the center of the range of maximal transmission although there are options to control this specification. Once the optimization reaches a desired tolerance, the computer system snaps the final optimized design parameters onto a discretized grid based on fabrication resolution. The default for this is 0.001 µm (e.g., 1 nm resolution). The final performance is evaluated with the snapped solution.

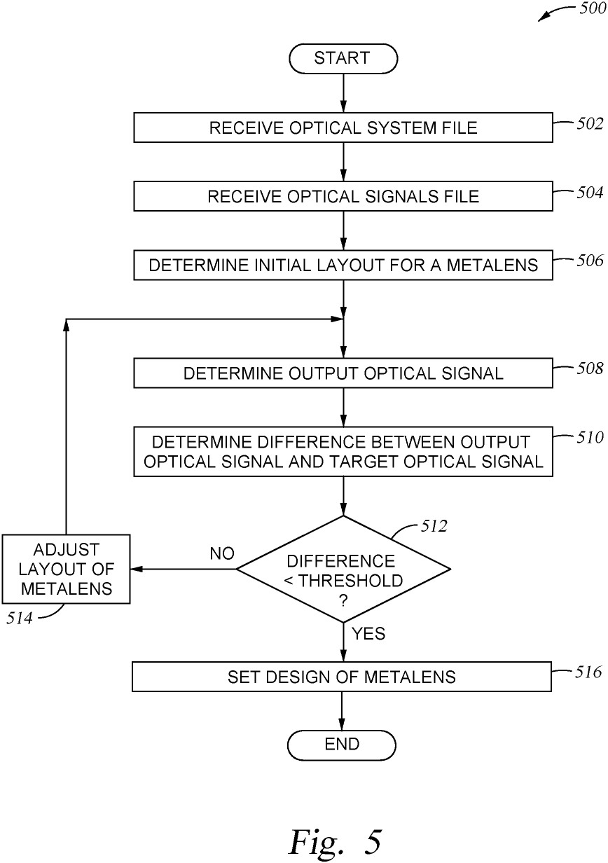

FIG. 5 is a flowchart of an example method 500 for designing a metalens. In particular embodiments, a computer system, such as the computer system 600 of FIG. 6, performs the method 500. By performing the method 500, the computer system determines one or more design perimeters for one or more metalenses in the optical system 100.

In 502, the computer system receives an optical system file 402. The optical system file 402 specifies the arrangement of metalenses and lenses in the optical system 100. For example, the optical system file 402 may specify the order of the lenses and metalenses in the optical system 100. Additionally, the optical system file 402 may specify the types of meta-atoms that are used in the metalenses of the optical system 100. Moreover, the optical system file 402 may specify the distances between the metalenses and lenses in the optical system 100.

In 504, the computer system receives an optical signals file 404. The optical signals file 404 specifies the characteristics of optical signals in the optical system 100. For example, the optical signals file 404 may specify characteristics of an incident optical signal to the optical system 100. The optical signals file 404 may specify a wavetype or a wavelength of the incident optical signal. Moreover, the optical signals file 404 may specify a target optical signal 412 for the optical system 100. The optical signals file 404 may indicate a desired wavelength or intensity profile for the target optical signal 412.

In 506, the computer system determines an initial layout 408 for a metalens in the optical system 100. The computer system may use an optimization process to determine the layout 408. For example, the computer system may provide the optical system file 402 and the optical signals file 404 as input to an optimization process 406. The optimization process 406 analyzes the information in the optical system file 402 and the optical signals file 404 to determine an initial layout 408 for the metalens. For example, the optimization process 406 may determine a design parameter, such as a width or diameter of meta-atoms in the metalens.

In 508, the computer system determines an output optical signal 410 of the metalens used the layout 408 determined in 506. The computer system may use any suitable technique for determining the output optical signal 410. For example, the computer system may simulate the path of an incident optical signal specified in the optical signals file 404 through the optical system 100. The computer system may determine how the different lenses and metalenses including the meta-atoms in the metalenses split or redirect the incident optical signal as the optical signal passes through the lenses and metalenses. By simulating the path of the optical signal, the computer system determines the output optical signal 410 of the optical system 100.

In 510, the computer system determines a difference 414 between the output optical signal 410 and the target optical signal 412 specified by the optical signals file 404. For example, the computer system may determine a difference in intensity profiles between the output optical signal 410 and the target optical signal 412. The intensity profile of the target optical signal 412 is scaled by a scaling factor before determining the difference 414. In 512, the computer system compares the difference 414 with a threshold 416. The threshold 416 may have been preselected by a designer of the optical system. For example, the threshold 416 may be 0.001.

If the difference 414 exceeds the threshold 416, the computer system proceeds to adjust the layout of the metalens in 514. For example, the computer system may provide the difference 414 as an input to the optimization process 406. The optimization process 406 then reevaluates the information in the optical system file 402 and the optical signals file 404 in view of the difference 414. The optimization process 406 then determines a new layout 408 for the metalens. The computer system then evaluates the new layout 408 to determine if a new difference 414 meets the threshold 416.

If the difference meets the threshold 416, the computer system sets the design of the metalens in 516. For example, the computer system may set the design of the metalens using the layout 408 with the difference 414 that met the threshold 416. In this manner, the computer system sets design parameters for the meta-atoms in the metalens such that the optical system 100 outputs an optical signal that is within the threshold 416 of the target optical signal 412. As a result, the computer system finds the optimal choice of the set of design parameters for each metalens in the optical system 100 to achieve the desired target optical signal 412 exploiting structural symmetry to improve speed.

FIG. 6 illustrates an example machine of a computer system 600 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM), a static memory 606 (e.g., flash memory, static random access memory (SRAM), etc.), and a data storage device 618, which communicate with each other via a bus 630.

Processing device 602 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 may also be one or more special-purpose processing devices such as an application specific integrated circuit (ASIC), a field programmable gate array (FPGA), a digital signal processor (DSP), network processor, or the like. The processing device 602 may be configured to execute instructions 626 for performing the operations and steps described herein.

The computer system 600 may further include a network interface device 608 to communicate over the network 620. The computer system 600 also may include a video display unit 610 (e.g., a liquid crystal display (LCD) or a cathode ray tube (CRT)), an alphanumeric input device 612 (e.g., a keyboard), a cursor control device 614 (e.g., a mouse), a graphics processing unit 622, a signal generation device 616 (e.g., a speaker), graphics processing unit 622, video processing unit 628, and audio processing unit 632.

The data storage device 618 may include a machine-readable storage medium 624 (also known as a non-transitory computer-readable medium) on which is stored one or more sets of instructions 626 or software embodying any one or more of the methodologies or functions described herein. The instructions 626 may also reside, completely or at least partially, within the main memory 604 and/or within the processing device 602 during execution thereof by the computer system 600, the main memory 604 and the processing device 602 also constituting machine-readable storage media.

In some implementations, the instructions 626 include instructions to implement functionality corresponding to the present disclosure. While the machine-readable storage medium 624 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 602 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system’s registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method for designing a metalens comprising:
receiving a description of an optical system, the description of the optical system indicating (i) characteristics of a first lens in the optical system, (ii) a meta-atom to be used in the first lens, and (iii) a first distance from the first lens;
receiving a description of optical signals, the description of the optical signals describing (i) an incident optical signal to the optical system and (ii) a target optical signal of the optical system;
determining, based at least in part on the characteristics of the first lens, the meta-atom, and the first distance, a first layout of a plurality of the meta-atom on the first lens;
determining a first output optical signal of the optical system based at least in part on the incident optical signal and the first layout of the plurality of the meta-atom on the first lens; and
setting a design of the first lens using the first layout based on whether a difference between the first output optical signal and the target optical signal meets a threshold.

2. The method of claim 1, further comprising:
based on the difference between the first output optical signal and the target optical signal not meeting the threshold, determining, based at least in part on the characteristics of the first lens, the meta-atom, the first distance, and the first layout, a second layout of the plurality of the meta-atom on the first lens;
determining a second output optical signal of the optical system with the incident optical signal and with the second layout of the plurality of the meta-atom on the first lens; and
setting the design of the first lens using the second layout based on whether a difference between the second output optical signal and the target optical signal meets the threshold.

3. The method of claim 1, wherein:
the description of the optical system further indicates characteristics of a second lens in the optical system and a second distance from the second lens;
the first distance is between the first lens and the second lens in the optical system; and
determining the first layout is further based on the characteristics of the second lens and the second distance.

4. The method of claim 1, wherein determining the first layout comprises determining a geometric design parameter for each of the plurality of the meta-atom on the first lens.

5. The method of claim 1, wherein the first layout is further based on different incident angles for each of the plurality of the meta-atom.

6. The method of claim 1, wherein the first layout is further based on a polarization of the optical signal and a response for each of the plurality of the meta-atom to the polarization.

7. The method of claim 1, wherein the first output optical signal is based at least in part on an absorbing boundary condition of a space within the first distance from the first lens.

8. The method of claim 1, wherein the difference comprises a difference between an intensity profile of the first output optical signal and an intensity profile of the target optical signal scaled by a scale factor.

9. The method of claim 1, wherein the difference is further based on a phase of the first output optical signal and on a phase of the target optical signal.

10. A system for designing a metalens comprising:
a memory; and
a processor communicatively coupled to the memory, the processor configured to:
receive (i) characteristics of a first lens in an optical system, (ii) a meta-atom to be used in the first lens, and (iii) a first distance from the first lens;
receive a description of (i) an incident optical signal to the optical system and (ii) a target optical signal of the optical system;
determine, based at least in part on the characteristics of the first lens, the meta-atom, and the first distance, a first layout of a plurality of the meta-atom on the first lens;
determine a first output optical signal of the optical system based at least in part on the incident optical signal and the first layout of the plurality of the meta-atom on the first lens; and
set a design of the first lens using the first layout based on whether a difference between the first output optical signal and the target optical signal meets a threshold.

11. The system of claim 10, wherein the processor is further configured to:
based on the difference between the first output optical signal and the target optical signal not meeting the threshold, determine, based at least in part on the characteristics of the first lens, the meta-atom, the first distance, and the first layout, a second layout of the plurality of the meta-atom on the first lens;
determine a second output optical signal of the optical system with the incident optical signal and with the second layout of the plurality of the meta-atom on the first lens; and
set the design of the first lens using the second layout based on whether a difference between the second output optical signal and the target optical signal meets the threshold.

12. The system of claim 10, wherein the processor is further configured to receive characteristics of a second lens in the optical system and a second distance from the second lens, wherein the first distance is between the first lens and the second lens in the optical system, and wherein determining the first layout is further based on the characteristics of the second lens and the second distance.

13. The system of claim 10, wherein determining the first layout comprises determining a geometric design parameter for each of the plurality of the meta-atom on the first lens.

14. The system of claim 10, wherein the first layout is further based on different incident angles for each of the plurality of the meta-atom.

15. The system of claim 10, wherein the first layout is further based on a polarization of the optical signal and a response for each of the plurality of the meta-atom to the polarization.

16. The system of claim 10, wherein the first output optical signal is based at least in part on an absorbing boundary condition of a space within the first distance from the first lens.

17. The system of claim 10, wherein the difference comprises a difference between an intensity profile of the first output optical signal and an intensity profile of the target optical signal scaled by a scale factor.

18. The system of claim 10, wherein the difference is further based on a phase of the first output optical signal and on a phase of the target optical signal.

19. A non-transitory computer readable medium storing instructions for designing a metalens that, when executed by a processor, cause the processor to:
receive (i) characteristics of a first lens in an optical system, (ii) a meta-atom to be used in the first lens, and (iii) a first distance from the first lens;
receive a description of (i) an incident optical signal to the optical system and (ii) a target optical signal of the optical system;
determine, based at least in part on the characteristics of the first lens, the meta-atom, and the first distance, a first layout of a plurality of the meta-atom on the first lens;
determine a first output optical signal of the optical system based at least in part on the incident optical signal and the first layout of the plurality of the meta-atom on the first lens; and
set a design of the first lens using the first layout based on whether a difference between the first output optical signal and the target optical signal meets a threshold.

20. The non-transitory computer readable medium of claim 19, wherein the instructions, when executed by the processor, further cause the processor to:
based on the difference between the first output optical signal and the target optical signal not meeting the threshold, determine, based at least in part on the characteristics of the first lens, the meta-atom, the first distance, and the first layout, a second layout of the plurality of the meta-atom on the first lens;
determine a second output optical signal of the optical system with the incident optical signal and with the second layout of the plurality of the meta-atom on the first lens; and
set the design of the first lens using the second layout based on whether a difference between the second output optical signal and the target optical signal meets the threshold.
